(19) United States
(12) Patent Application Publication
(10) Pub. No.: US 2010/0109160 A1
(43) Pub. Date: May 6, 2010

(54) SEMICONDUCTOR DEVICE AND METHOD OF MANUFACTURING THE SAME

(75) Inventors: Hideaki SAKAGUCHI, Nagano (JP); Koichi Toya, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/610,614

(22) Filed: Nov. 2, 2009

(30) Foreign Application Priority Data
Nov. 4, 2008 (JP) 2008-283201

(51) Int. Cl. H01L 23/498; H01L 21/60

(52) U.S. Cl. 257/737; 438/613; 438/113; 257/E23.068; 257/E21.508

(57) ABSTRACT

A method of manufacturing a semiconductor device, includes the steps of preparing a semiconductor wafer having a connection pad, forming an insulating dam layer in which an opening portion is provided in an area including the connection pad, on the semiconductor wafer, and forming a bump electrode by mounting a conductive ball on the connection pad in the opening portion of the insulating dam layer.

### CROSS-REFERENCE TO RELATED APPLICATIONS

This application is based on and claims priority of Japanese Patent Application No. 2008-283201 filed on Nov. 4, 2008, the entire contents of which are incorporated herein by reference.

### BACKGROUND OF THE INVENTION

1. Field of the Invention

The present invention relates to a semiconductor device and a method of manufacturing the same and, more particularly, a semiconductor device including bump electrodes as connection terminals and a method of manufacturing the same.

2. Description of the Related Art

In the prior art, there are the semiconductor devices in which the bump electrodes made of solder, or the like are provided as the connection terminals. As the method of forming the bump electrode, there is the method of obtaining the bump electrodes by mounting the solder ball on the connection pads respectively and applying the reflow heating to them.

In Patent Literature 1 (Patent Application Publication (KOKAI) Sho 64-11071), such a method is set forth that a thin solder layer is formed on the connection electrodes of the electronic component, and then the solder balls are sprayed to the solder layers and adhered thereto in a state that the electronic component is held at a solder fusing temperature or more to fuse the solder layers.

Also, in Patent Literature 2 (Patent Application Publication (KOKAI) Hei 7-153765), it is set forth that the case in which the metal balls are housed is vibrated finely, then the metal balls which floats by the vibration are adsorbed into the hole of the alignment substrate, then this alignment substrate is carried to the connection stage, and then the metal balls are joined to the electrode pads of the semiconductor chip.

As explained in the column of related art described later, upon forming the bump electrodes by mounting the solder balls on the connection pads of the silicon wafer and then applying the reflow heating to them, because the connection pads are formed to have a convex shape, often the solder balls are rolled and moved outside from the connection pads.

For this reason, the bridging defect in which the bump electrodes are connected mutually occurs, or two solder balls are mounted on one connection pad, thereby extra-large bump electrodes are formed. As a result, such a problem exists that a reduction in production yield is easily caused.

### SUMMARY OF THE INVENTION

It is an object of the present invention to provide a semiconductor device in which bump electrodes are formed by mounting conductive balls on connection pads with good reliability, and a method of manufacturing the same.

The present invention is concerned with a method of manufacturing a semiconductor device, which includes the steps of preparing a semiconductor wafer having a connection pad; forming an insulating dam layer in which an opening portion is provided in an area including the connection pad, on the semiconductor wafer; and forming a bump electrode by mounting a conductive ball on the connection pad in the opening portion of the insulating dam layer.

In the present invention, the insulating dam layer in which the opening portions are provided in the areas including the connection pads of the semiconductor wafer is formed on the semiconductor wafer. The insulating dam layer is provided so as to position the conductive balls such that, when the conductive balls are to be mounted on the connection pads, the conductive balls are not rolled and moved outside from a surface of the connection pad. Then, the bump electrodes are formed by mounting the conductive balls on the connection pads in the opening portions of the insulating dam layer.

In particular, when the conductive balls are formed of the solder ball, even though the solder balls are moved during the reflow heating, the insulating dam layer acts as the stopper to block the movement of the conductive balls. Therefore, such a possibility can be eliminated that the solder balls roll and move in the lateral direction, and the bump electrodes are formed on the connection pads with good reliability.

Accordingly, such failure can be solved that the bridging defect in which the bump electrodes are connected mutually occurs, or two solder balls are mounted on one connection pad, thereby extra-large bump electrodes are formed. Therefore, even though a pitch between the connection pads is made narrower, the bump electrodes can be formed with good yield.

In the present invention, the conductive balls may be mounted on the connection pads of the semiconductor wafer to pass through the opening portions of the mask, or the conductive balls may be mounted on the connection pads in a maskless mode.

When the conductive balls are mounted in a maskless mode, the semiconductor wafer is arranged to direct the connection pad thereof downward, a ball case in which a large number of conductive balls are housed is arranged under the semiconductor wafer, and by flying the conductive ball toward the semiconductor wafer side while vibrating the ball case up and down, the conductive ball is made to adhere onto an adhesive material such as a flux, a conductive paste, or the like provided on the connection pad.

By doing so, the solder balls that are not adhered onto the connection pads of the silicon wafer are recovered automatically into the ball case by gravity. Therefore, the extra solder balls can be recovered effectively and surely rather than the method that mounts the conductive balls through the opening portions of the mask.

The insulating dam layer may be removed, or left as it is, as the need arises. In the case that the insulating dam layer is left, a thickness of the insulating dam layer is set thinner than a height of the bump electrode (conductive ball) such that the connection portions of the bump electrodes are exposed.

Also, the present invention is concerned with a semiconductor device, which includes a semiconductor substrate having a connection pad; a bump electrode connected to the connection pad, and projecting upward; and an insulating dam layer which is formed on the silicon substrate and in which an opening portion is provided in an area containing the bump electrode; wherein a thickness of the insulating dam layer is set thinner than a height of the bump electrode, and a clearance is provided between the bump electrode and a side surface of the opening portion of the insulating dam layer.

The semiconductor device of the present invention is manufactured by the above manufacturing method such that the conductive ball is mounted on the connection pads in the opening portions of the insulating dam layer respectively and the insulating dam layer is left. Since the opening portion of the insulating dam layer is set to a size slightly larger in diameter than the conductive ball, a clearance is provided between the bump electrode and the side surface of the opening portion of the insulating dam layer.

In the preferred mode of the present invention, a thickness of the insulating dam layer is set in a range of 20 to 50% of a height of the bump electrode such that the solder ball can be positioned stably in the opening portion of the insulating dam layer and also the connection portion of the bump electrode can be exposed sufficiently.

As explained above, in the present invention, the conductive balls can be mounted on the connection pads of the semiconductor wafer with good reliability and the bump electrodes can be formed with good yield.

### BRIEF DESCRIPTION OF THE DRAWINGS

FIGS. 1A to 1D are sectional views (#1) showing a method of manufacturing a semiconductor device in the related art;

FIGS. 2A to 2C are sectional views (#2) showing the method of manufacturing the semiconductor device in the related art;

FIG. 3 is a sectional view and a plan view (#1) showing a method of manufacturing a semiconductor device according to a first embodiment of the present invention;

FIGS. 4A to 4C are sectional views and a plan view (#2) showing the method of manufacturing the semiconductor device according to the first embodiment of the present invention;

FIGS. 5A to 5C are sectional views (#3) showing the method of manufacturing the semiconductor device according to the first embodiment of the present invention;

FIGS. 6A to 6C are sectional views (#4) showing the method of manufacturing the semiconductor device according to the first embodiment of the present invention;

FIGS. 7A to 7C are sectional views showing a method of manufacturing a semiconductor device according to a second embodiment of the present invention;

FIGS. 8A and 8B are sectional views (#1) showing a method of manufacturing a semiconductor device according to a third embodiment of the present invention; and

FIGS. 9A and 9B are sectional views (#2) showing the method of manufacturing the semiconductor device according to the third embodiment of the present invention.

### DETAILED DESCRIPTION OF THE PREFERRED EMBODIMENTS

Embodiments of the present invention will be explained with reference to the accompanying drawings hereinafter.

### Related Art

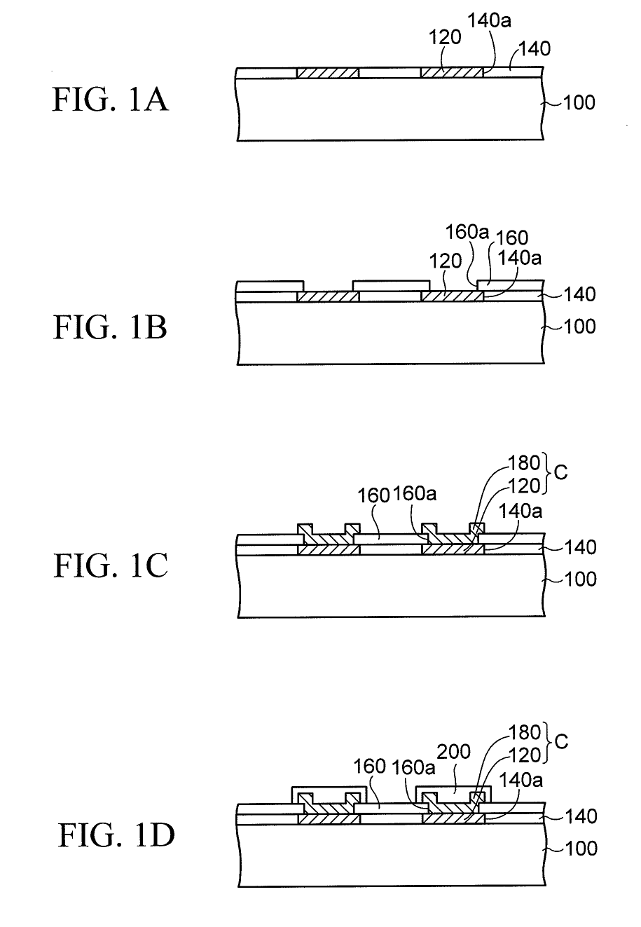

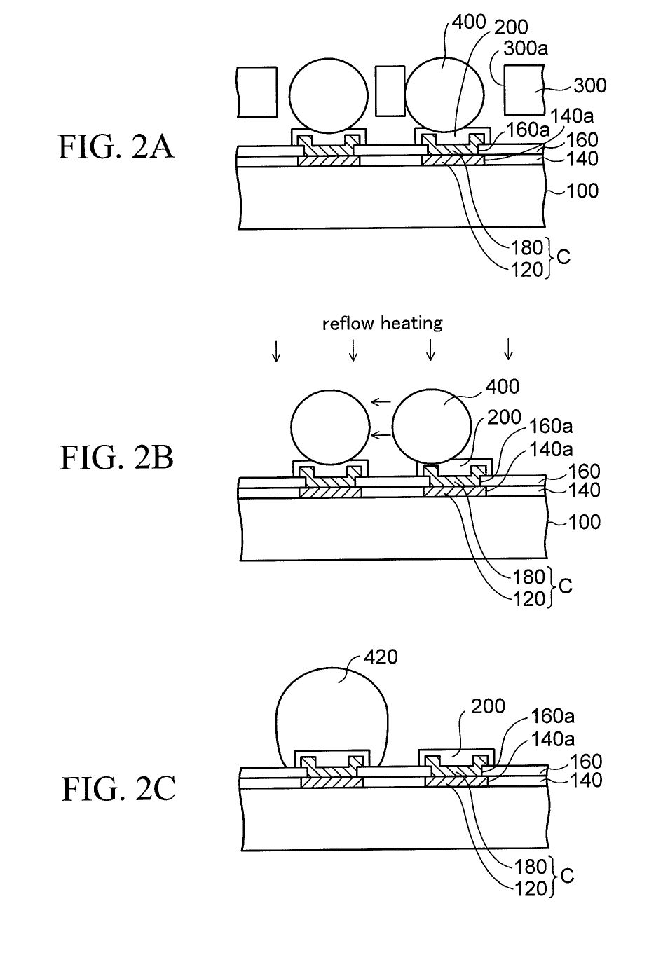

FIGS. 1A to 1D and FIGS. 2A to 2C are sectional views showing a method of manufacturing a semiconductor device in the related art associated with the present invention. In the method of manufacturing the semiconductor device in the related art, as shown in FIG. 1A, first, a silicon wafer 100 having connection electrodes 120 and a passivation layer 140 in which opening portions 140a from which the connection electrode 120 is exposed are provided, on the upper surface side, is prepared. Although not particularly shown, circuit elements such as transistors, etc. and a multilayer wiring for connecting the elements are provided on the silicon wafer 100, and the connection electrodes 120 are connected to the multilayer wiring.

Then, as shown in FIG. 1B, a protection insulating layer 160 in which opening portions 160a are provided on the connection electrodes 120 is formed on the passivation layer 140. Then, as shown in FIG. 1C, metal barrier layers 180 connected to the connection electrodes 120 are formed as the pattern on the connection electrodes 120. Accordingly, connection pads C constructed by the connection electrode 120 and the metal barrier layer 180 are provided on the uppermost surface of the silicon wafer 100. The metal barrier layer 180 in the connection pad C is arranged convexly from on the connection electrode 120 onto the protection insulating layer 160.

Then, as shown in FIG. 1D, a flux 200 is formed as the pattern on the connection pads C of the silicon wafer 100.

Next, as shown in FIG. 2A, a mask 300 in which opening portions 300a corresponding to the connection pads C of the silicon wafer 100 are provided is prepared. Then, the mask 300 is arranged over the silicon wafer 100. At this time, the mask 300 is aligned and arranged such that the opening portions 300a of the mask 300 are arranged on the connection pads C of the silicon wafer 100.

Then, a large number of solder balls 400 are supplied onto the mask 300, and then the solder balls 400 are swept and made to move toward one end side of the mask 300 by a brush (not shown). Thus, the solder balls 400 pass through the opening portions 300a of the mask 300 individually, and are arranged and adhered onto the connection pads C of the silicon wafer 100.

Then, as shown in FIG. 2B, the mask 300 is removed from the silicon wafer 100. At this time, because the connection pads C of the silicon wafer 100 are formed convexly, often the solder balls 400 are rolled and arranged to displace outside from the center portions of the connection pads C.

Then, as similarly shown in FIG. 2B, the reflow heating is applied to the solder balls 400, and then the residue of the flux 200 is removed. In this case, since the flux 200 flows in the lateral direction during the reflow heating, sometimes the solder balls 400 which are arranged to be displaced are further pushed and rolled in the lateral direction, and furthermore contact the adjacent solder balls 400.

When such situation occurs, as shown in FIG. 2C, two solder balls 400 are mounted on one connection pad C of the silicon wafer 100. Thus, extra-large bump electrode 420 which projects upward in contrast to other bump electrodes is formed. At the same time, the connection pad C on which no bump electrode is formed is produced.

Otherwise, when the other solder ball falls into a space between the normal solder balls 400 that are arranged on the connection pads C, the bridging defect in which the adjacent bump electrodes are connected mutually caused.

Accordingly, in particular, when a pitch between the connection pads C is made narrower, it is feared that a reduction in yield becomes conspicuous.

Therefore, the embodiments of the present invention explained hereunder can solve the above drawback.

### First Embodiment

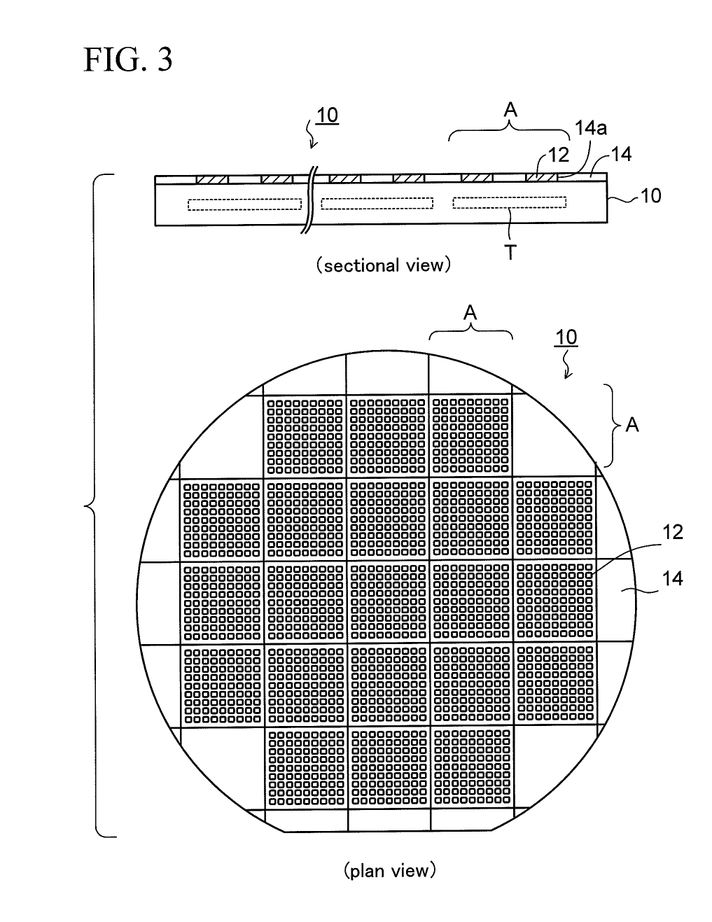

FIG. 3 to FIG. 6C are sectional views (partially plan views) showing a method of manufacturing a semiconductor device according to a first embodiment of the present invention. In the method of manufacturing the semiconductor device according to the first embodiment, first, a silicon wafer 10 as shown FIG. 3 is prepared. In the present embodiment, the silicon wafer 10 is illustrated as the semiconductor wafer.

As shown in a sectional view of FIG. 3, the silicon wafer 10 has connection electrodes 12 and a passivation layer 14 (insulating layer) in which opening portions 14a for exposing the connection electrode 12 are provided, on the uppermost surface.

The connection electrode 12 is formed of aluminum or aluminum alloy, for example. The passivation layer 14 is formed of either a silicon nitride layer and a polyimide resin layer, or their stacked film, for example.

Also, a plurality of element forming areas T in which circuit elements such as transistor (semiconductor element), capacitor, resistor, etc. are formed are provided in the silicon wafer 10. A multilayer wiring (not shown) for connecting various elements is formed on the element forming areas T, and the multilayer wiring is connected to the connection electrodes 12.

By reference to a plan view of FIG. 3, a large number of chip areas A containing the element forming areas T are provided to the silicon wafer 10.

In an example of a plan view of FIG. 3, the connection electrodes 12 are arranged as the area array type, and the connection electrodes 12 are arranged like a grid on the whole chip area A respectively. Otherwise, the connection electrodes 12 may be arranged as the peripheral type, and the connection electrodes 12 may be arranged on the peripheral portion of each chip area A respectively. The silicon wafer 10 is cut such that respective chip areas A are obtained, and becomes individual semiconductor chips (semiconductor devices) later.

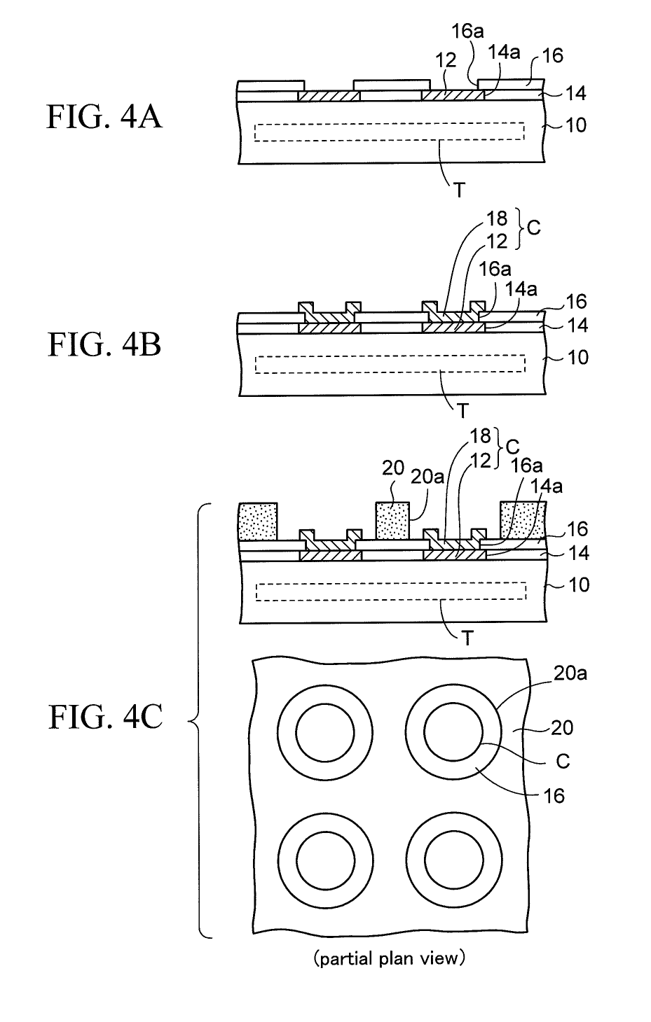

Explanation will be continued from the next step by referring a partial sectional view of FIG. 3. As shown in FIG. 4A, a protection insulating layer 16 in which opening portions 16a are provided on the connection electrodes 12 is formed on the silicon wafer 10. The protection insulating layer 16 is formed by patterning a photosensitive polyimide resin by the photolithography, for example.

Then, as shown in FIG. 4B, a metal barrier layer 18 is formed as the pattern on the connection electrodes 12. The metal barrier layer 18 is also called UBM (Under Bump Metal). The connection pad C of the silicon wafer 10 is constructed by the connection electrode 12 and the metal barrier layer 18.

As an example of the preferred layer structure of the metal barrier layer 18, a titanium (Ti) layer or a chromium (Cr) layer/a nickel (Ni) layer or a copper (Cu) layer/a gold (Au) layer is formed sequentially from a bottom. A palladium (Pd) layer may be formed further between the nickel layer or the copper layer and the gold layer. Otherwise, a titanium-tungsten (TiW) layer may be formed further between the titanium layer or the chromium layer and the nickel layer or the copper layer.

As the method of forming the metal barrier layer 18, the metal layer is formed with multi layer structure by the sputter method, or the like, and then the metal layer is patterned by the photolithography. Otherwise, the metal barrier layer 18 may be formed by a lift-off method. In the lift-off method, a resist in which opening portions are provided on the connection pads C is formed, then a metal layer is formed with multi layer structure on the whole surface by the sputter method, and then the resist is removed.

The metal barrier layer 18 of the connection pad C is arranged convexly from on the connection electrode 12 onto the protection insulating layer 16 which is formed to the side of the connection electrode 12.

Then, as shown in FIG. 4C, an insulating dam layer 20 in which opening portions 20a are provided in the areas including the connection pads C is formed on the protection insulating layer 16. The insulating dam layer 20 is provided so as to position the solder balls such that, when the solder balls are mounted on the connection pads C, the solder balls are not rolled and moved outside from the surface of the connection pads C. Therefore, as shown in a partial plan view of FIG. 4C, the opening portion 20a of the insulating dam layer 20 is formed to surround the connection pad C.

The opening portion 20a of the insulating dam layer 20 is set to a size slightly larger diameter than the solder ball such that the solder ball can be arranged stably. For example, when the solder ball of 100 μm diameter is mounted on the connection pad C, a diameter of the opening portion 20a of the insulating dam layer 20 is set to 130 μm.

Also, a thickness of the insulating dam layer 20 is set to a thickness that can block the movement when the solder ball is rolled in the opening portion 20a. As described later, when the solder ball is mounted from the opening portion of the mask, preferably a thickness of the insulating dam layer should be set in a range of 20 to 50% of a height of the solder ball.

As the method of forming the insulating dam layer 20, the opening portions 20a are formed on the connection pads C by pasting a dry film resist on the silicon wafer 10, and then exposing/developing the resist by the photolithography. Otherwise, a liquid resist may be coated on the silicon wafer 10, and then the opening portions 20a may be formed similarly by the photolithography.

Alternatively, the opening portions 20a may be formed on the connection pads C by adhering a resin film such as a polyimide resin, or the like on the silicon wafer 10 by a silicone-based adhesive, and then processing the resin film by the dry etching or the laser.

In this case, a metal mask made of copper, or the like is patterned on the resin film, and the resin film is processed through the opening portion of the metal mask by the dry etching or the laser. Then, the metal mask (copper, or the like) is removed selectively to the underlying film by the wet etching.

When the opening portions 20a of the insulating dam layer 20 are formed by the photolithography, the dry etching or the laser, the connection electrodes 12 (aluminum) of the silicon wafer 10 are protected by the metal barrier layers 18 located on the connection electrodes 12. Therefore, it is not feared that the connection electrodes 12 and the circuit elements under thereof are damaged.

As described layer, the insulating dam layer 20 may be removed, or may be left as it is, after the bump electrodes are formed by mounting the solder balls. In the case that the insulating dam layer 20 is removed, it is preferable that the easily peelable resist should be employed. Also, In the case that the insulating dam layer 20 is removed, a thickness of the insulating dam layer 20 may be set arbitrarily and may be set thicker than a height of a solder ball 40a.

Otherwise, in the case that the insulating dam layer 20 is left, a thickness of the insulating dam layer 20 is set thinner than a height of the bump electrode obtained by applying the reflow heating to the solder balls. Also, in the case that the insulating dam layer 20 is left, any insulating material may be employed if such material can be patterned. Various insulating materials can be employed in addition to the resist and the resin film.

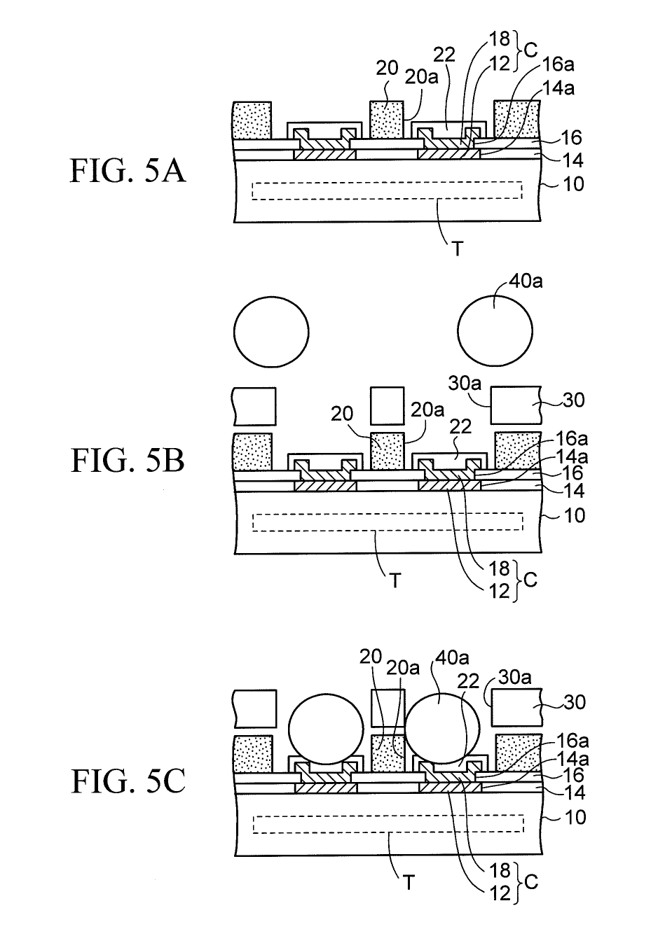

Then, as shown in FIG. 5A, fluxes 22 are formed as the pattern on the connection pads C of the silicon wafer 10 by the printing, or the like.

Then, as shown in FIG. 5B, the silicon wafer 10 is arranged on the stage of the ball mounting equipment (not shown), and a mask 30 is arranged over the silicon wafer 10. Opening portions 30a corresponding to the connection pads C (the opening portions 20a in the insulating dam layer 20) of the silicon wafer 10 are provided in the mask 30.

Then, the mask 30 is aligned and arranged on the silicon wafer 10 such that the opening portions 30a of the mask 30 are arranged on the connection pads C of the silicon wafer 10. Then, a large number of solder balls 40a (conductive balls) are supplied onto the mask 30 from a ball supplying means (not shown).

Then, as shown in FIG. 5C, the solder balls 40a are swept toward one end side of the mask 30 by moving the brush (not shown) in the horizontal direction. Thus, the solder balls 40a are passed through the opening portions 30a of the mask 30 respectively. Accordingly, the solder balls 40a are arranged and adhered onto the fluxes 22 on the connection pads C of the silicon wafer 10.

Otherwise, an air may be sprayed to the solder balls 40a and the solder balls 40a may be moved. Thereby, the solder balls 40a pass through the opening portions 30a of the mask 30 and then the solder balls 40a are adhered onto the connection pads C. Then, extra solder balls 40a left on the mask 30 are recovered at the end portion of the mask 30.

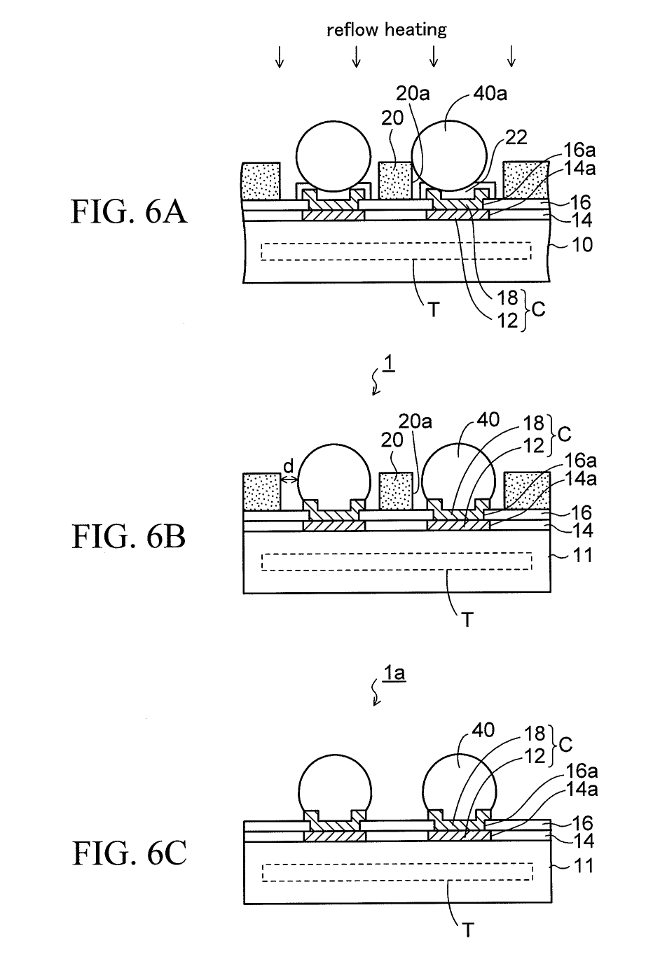

Then, as shown in FIG. 6A, the mask 30 is separated from the silicon wafer 10. At this time, since the connection pads C are shaped convexly, sometime the solder balls 40a roll and move on the surface of the connection pads C. However, in the present embodiment, since the insulating dam layer 20 is formed around the connection pads C, the solder balls 40a are positioned and arranged in the opening portions 20a. Then, the reflow heating is applied to the solder balls 40a.

By this matter, as shown in FIG. 6B, bump electrodes 40 which are connected to the connection pads C and project upward are obtained.

At this time, even when the solder ball 40a displaced slightly from the center portion of the connection pad C is pushed in the lateral direction by the outflow of the flux 22, the solder ball 40a is dammed up by the insulating dam layer 20. Thus, the solder ball 40a never deviates from the connection pad C. Also, the solder ball 40a is led toward the center side of the connection pad C by the self-align effect produced by a surface tension of the fused solder during the reflow heating.

Then, as also shown in FIG. 6B, the silicon wafer 10 is cut such that respective chip areas A (plan view in FIG. 3) of the silicon wafer 10 are obtained. Accordingly, the silicon wafer 10 is divided into individual silicon substrates 11, and a semiconductor device 1 (semiconductor chip) can be obtained.

In the present embodiment, the solder ball 40a which is formed of solder over the whole is illustrated as the conductive ball. In this case, the ball formed by coating a core ball made of resin with a solder layer or the ball formed by coating an outer surface of a core ball made of copper with a solder layer, or the like may be employed.

Otherwise, in the case that the connection method other than the solder connection is employed, the conductive ball made of various conductive material can be employed.

As explained above, in the method of manufacturing the semiconductor device of the first embodiment, the insulating dam layer 20 in which the opening portions 20a are provided on the connection pads C is formed on the silicon wafer 10, and then the solder ball 40a is mounted on the connection pads C respectively. Accordingly, the solder balls 40a are positioned and arranged in the opening portions 20a of the insulating dam layer 20.

Therefore, even when the flux 22 flows to the outer side upon the reflow heating, the movement of the solder ball 40a is blocked by the insulating dam layer 20. As a result, the bump electrode 40 can be formed on the connection pads C with good reliability respectively.

In this manner, the solder balls 40a can be mounted surely on the connection pads C having the convex shape over which the solder ball 40a is ready to roll. Therefore, even though a pitch between the connection pads C is made narrower, the bump electrodes 40 can be formed with good yield.

In FIG. 6B, the semiconductor device 1 in which the insulating dam layer 20 is left as it is, is illustrated.

As shown in FIG. 6C, a semiconductor device 1a in which the insulating dam layer 20 does not exist may be manufactured by removing the insulating dam layer 20 prior to the cutting of the silicon wafer 10. In the case that the insulating dam layer 20 is removed, the insulating dam layer 20 is formed of the resist and is removed easily by the resist stripper liquid, or the like.

As shown in FIG. 6B, in the semiconductor device of the present embodiment, the element forming area T in which the circuit element such as the transistor, or the like is formed is provided in the silicon substrate 11 (semiconductor substrate), and the element forming area T is connected electrically to the connection electrodes 12 via the multilayer wiring (not shown). The passivation layer 14 (insulating layer) is formed on the side of the connection electrodes 12.

Also, the protection insulating layer 16 in which the opening portions 16a are provided on the connection electrodes 12 is formed on the passivation layer 14. The metal barrier layer 18 is formed as the pattern on the connection electrodes respectively. The connection pad C is constructed by the connection electrode 12 and the metal barrier layer 18. The metal barrier layer 18 of the connection pad C is formed convexly from on the connection electrode 12 onto the protection insulating layer 16.

The bump electrode 40 which is connected to the connection pad C and projects upward is provided on the connection pad C. Also, the insulating dam layer 20 in which the opening portions 20a are provided on the bump electrodes 40 and their neighborhoods is formed on the protection insulating layer 16.

In the semiconductor device 1 of the present embodiment, the insulating dam layer 20 in which the opening portions 20a whose diameter is set to a size slightly larger diameter than the solder ball 40a are provided is formed, and then the bump electrodes 40 are formed by mounting the solder ball 40a in the opening portions 20a. Therefore, a clearance d is provided between the bump electrode 40 and the opening portion 20a of the insulating dam layer 20.

In this case, the bump electrode 40 may contact the side surface of the opening portion 20a of the insulating dam layer 20 at the location where the solder ball 40a is displaced slightly from the center portion of the connection pad C.

Also, preferably a thickness of the insulating dam layer 20 should be set in a range of 20 to 50% of a height of the bump electrode 40. Accordingly, the solder ball 40a can be positioned stably in the opening portion 20a of the insulating dam layer 20, and also the connection portion of the bump electrode 40 can be exposed sufficiently even though the insulating dam layer 20 is still left. Then, the top end sides of the bump electrodes 40 of the semiconductor device 1 are connected electrically to the connection portions of the wiring substrate (mounting substrate).

### Second Embodiment

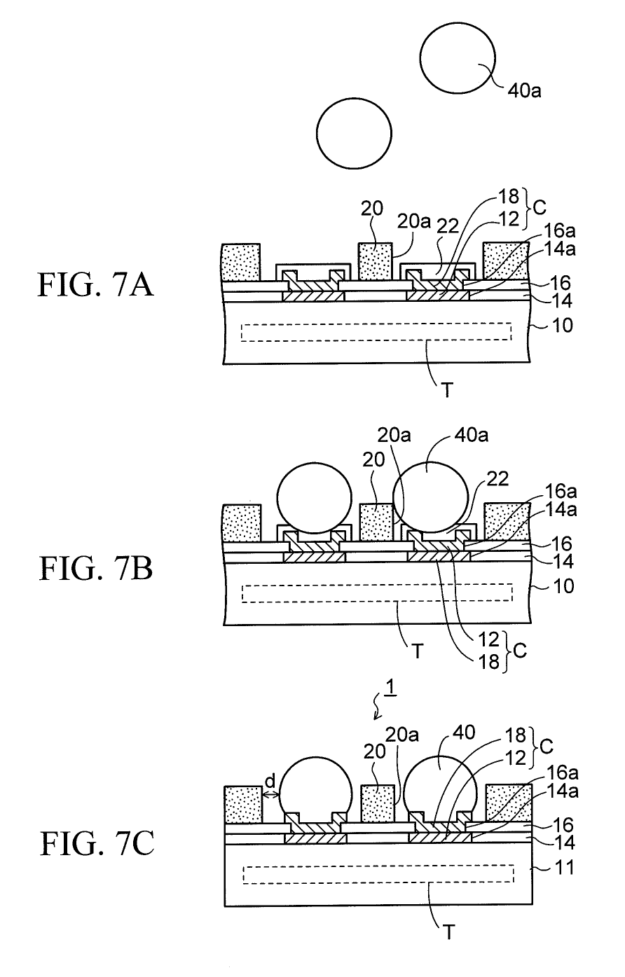

FIGS. 7A to 7C are sectional views showing a method of manufacturing a semiconductor device according to a second embodiment of the present invention. A feature of the second embodiment resides in that no mask is employed in mounting the solder balls. In the second embodiment, explanation of the same steps and the same elements as those in the first embodiment will be omitted herein by affixing the same reference symbols to them.

As shown in FIG. 7A, the silicon wafer 10 having the same structure as that in FIG. 5A of the first embodiment is prepared. That is, the insulating dam layer 20 in which the opening portions 20a are provided on the connection pads C is formed on the silicon wafer 10, and the flux 22 is coated on the connection pads C respectively.

Then, the silicon wafer 10 is arranged on the stage of the ball mounting equipment (not shown), and a large number of solder balls 40a are supplied to the silicon wafer 10 from the ball supplying means (not shown) without through the mask. Then, an air is sprayed to the solder balls 40a supplied onto the silicon wafer 10 from the lateral direction, so that the solder balls 40a are moved to one end side of the silicon wafer 10.

Accordingly, as shown in FIG. 7B, the solder balls 40a supplied onto the silicon wafer 10 are transferred into the opening portions 20a of the insulating dam layer 20 respectively. Otherwise, the solder balls 40a may be transferred into the opening portions 20a of the insulating dam layer 20 by vibrating the silicon wafer 10 up and down instead of the spraying of the air.

The extra solder balls arranged on the insulating dam layer 20 are blown off from on the silicon wafer 10 to the outside by the air. Since the solder balls 40a arranged on the connection pads C of the silicon wafer 10 are adhered onto the flux 22, such solder balls 40a are not blown off and still left.

Then, as shown in FIG. 7C, like the first embodiment, the bump electrodes 40 which are connected to the connection pads C and project upward are formed by applying the reflow heating to the solder balls 40a. Then, the silicon wafer 10 is cut, so that individual semiconductor devices 1 similar to that in the first embodiment can be obtained.

In the second embodiment, the solder balls 40a are mounted without using the mask. Thus, when the insulating dam layer 20 is too low, it is feared that the solder balls 40a escape from the opening portion 20a. Therefore, in order to mount the solder balls 40a stably in a maskless mode, it is preferable that a thickness of the insulating dam layer 20 should be set to a range of 50 to 130% of a diameter of the solder ball 40a.

In this regard, in the case that the insulating dam layer 20 is left, a thickness of the insulating dam layer 20 is set thinner than a height of the solder ball 40a (bump electrode 40) so as to expose the connection portions of the bump electrodes 40.

In FIG. 7C, the semiconductor device 1 in which the insulating dam layer 20 is left is illustrated. In this case, the semiconductor device in which the insulating dam layer 20 does not exist may be obtained by removing the insulating dam layer 20 prior to the cutting of the silicon wafer 10.

The second embodiment can achieve the similar advantages as those in the first embodiment. In addition to this, a reduction in cost can be achieved because the mask can be omitted.

### Third Embodiment

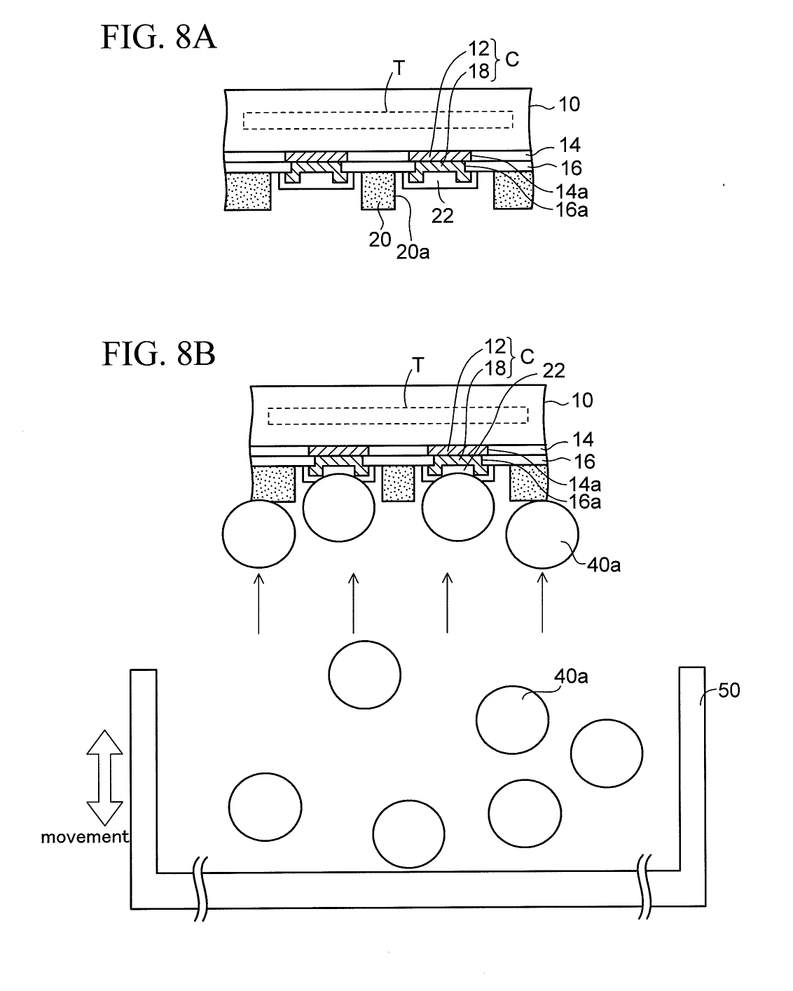

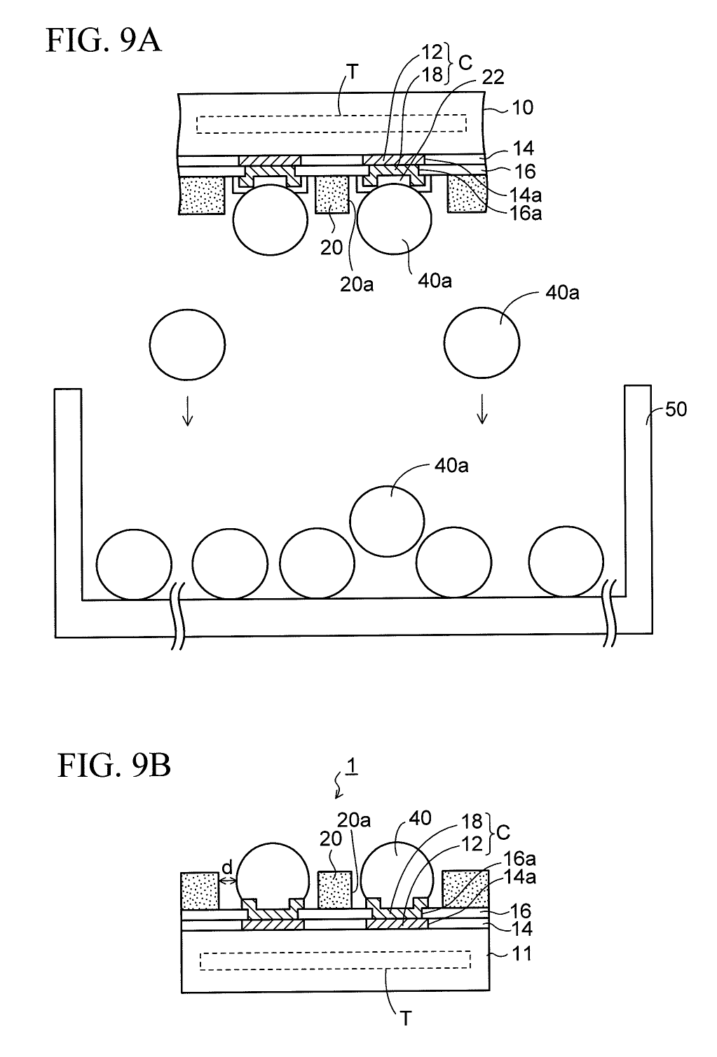

FIGS. 8A and 8B and FIGS. 9A and 9B are sectional views showing a method of manufacturing a semiconductor device according to a third embodiment of the present invention. In the above second embodiment, since the solder balls 40a are mounted in a maskless mode to direct the connection pads C of the silicon wafer 10 upward, it is feared that much time and effort are needed in removing the extra solder balls 40a.

A feature of the third embodiment resides in that the solder balls are mounted in a state that the connection pads of the silicon wafer are directed downward. In the third embodiment, explanation of the same steps and the same elements as those in the first embodiment will be omitted herein by affixing the same reference symbols to them.

In the third embodiment, as shown in FIG. 8A, first, the silicon wafer 10 having the same structure as that in FIG. 5A of the first embodiment is prepared. That is, the insulating dam layer 20 in which the opening portions 20a are provided on the connection pads C is formed on the silicon wafer 10, and the flux 22 is coated on the connection pads C respectively.

Then, the silicon wafer 10 is reversed up and down, and the connection pads C are directed downward. The silicon wafer 10 is supported by a supporting means of the ball mounting equipment (not shown) in a state that the connection pads C are directed downward.

Then, as shown in FIG. 8B, the ball mounting equipment (not shown) is equipped with a ball case in which a large number of solder balls 40a are housed. The ball case 50 is arranged under the silicon wafer 10. The upper side of the ball case 50 is opened.

Then, the solder balls 40a in the ball case 50 are flown to the lower surface of the silicon wafer 10 by vibrating the ball case 50 up and down. At this time, the solder balls 40a flown to the connection pads C of the silicon wafer 10 are adhered onto the fluxes 22 and mounted on the connection pads C. The ball case 50 is vibrated up and down until the solder ball 40a is mounted on all connection pads C of the silicon wafer 10 respectively.

Here, in the present embodiment, the flux 22 is illustrated as the adhesive material on which the solder ball 40a is mounted. But the conductive paste, or the like may be employed.

Then, as shown in FIG. 9A, when the mounting of the solder balls 40a is completed, the solder balls 40a which are not adhered onto the connection pads C of the silicon wafer 10 fall down into the ball case 50 by gravity and are recovered automatically.

In this manner, in the third embodiment, the solder balls 40a are adhered onto the fluxes 22 on the connection pads C from the lower side to direct the connection pads C of the silicon wafer 10 downward. Therefore, even if the operation of removing the extra solder balls 40a is not carried out, the removing residue of the extra solder balls 40a never occurs.

As a result, the extra solder balls can be recovered extremely effectively and surely. Also, since preparation of the mask is not needed, a reduction in cost can be achieved.

In the third embodiment, in order to transfer stably the solder ball 40a in the opening portion 20a of the insulating dam layer 20, it is preferable that the thickness of the insulating dam layer 20 should be set to a range of 50 to 130% of the diameter of the solder ball 40a. Also similarly, in the case that the insulating dam layer 20 is left, the thickness of the insulating dam layer 20 is set thinner than the height of the solder ball 40a (bump electrode 40).

Then, as shown in FIG. 9B, like the first embodiment, the bump electrodes 40 which are connected to the connection pads C and project upward are obtained by applying the reflow heating to the solder balls 40a.

Then, the silicon wafer 10 is cut, and individual semiconductor devices 1 similar to those in the first embodiment can be obtained.

In FIG. 9B, the semiconductor device 1 in which the insulating dam layer 20 is left is illustrated. In this case, the semiconductor device in which the insulating dam layer 20 does not exist may be obtained by removing the insulating dam layer 20 prior to the cutting of the silicon wafer 10.

The third embodiment can achieve the similar advantages to those in the first and second embodiments. In addition to this, the connection pads C of the silicon wafer 10 are directed downward, and the solder balls 40a are mounted onto the connection pads C in a maskless mode from the lower side. As a result, the extra solder balls can be removed effectively and surely, and a production efficiency and a production yield can be improved much more.

What is claimed is:

1. A semiconductor device, comprising:
a semiconductor substrate having a connection pad;
a bump electrode connected to the connection pad, and projecting upward; and
an insulating dam layer formed on the silicon substrate and in which an opening portion is provided in an area including the bump electrode;
wherein a thickness of the insulating dam layer is set thinner than a height of the bump electrode, and a clearance is provided between the bump electrode and a side surface of the opening portion of the insulating dam layer.

2. A semiconductor device according to claim 1, wherein a thickness of the insulating dam layer is set in a range of 20 to 50% of a height of the bump electrode.

3. A semiconductor device according to claim 1, wherein the connection pad is constructed by a connection electrode made of aluminum or aluminum alloy and a metal barrier layer formed on the connection electrode, and
the metal barrier layer is arrange convexly from on the connection electrode onto an insulating layer formed to a side of the connection electrode.

4. A method of manufacturing a semiconductor device, comprising the steps of:
preparing a semiconductor wafer having a connection pad;
forming an insulating dam layer in which an opening portion is provided in an area including the connection pad, on the semiconductor wafer; and
forming a bump electrode by mounting a conductive ball on the connection pad in the opening portion of the insulating dam layer.

5. A method of manufacturing a semiconductor device, according to claim 4, after the step of forming the bump electrode, further comprising the step of:
removing the insulating dam layer.

6. A method of manufacturing a semiconductor device, according to claim 4, wherein, in the step of forming the bump electrode, at least an outer surface portion of the conductive ball is formed of solder, and
after the conductive ball is mounted, the bump electrode connected to the connection pad is obtained by applying a reflow heating to the conductive ball.

7. A method of manufacturing a semiconductor device, according to claim 4, wherein the step of forming the bump electrode includes,
arranging a mask in which an opening portion corresponding to the connection pad is provided, on the semiconductor wafer, and mounting the conductive ball on the connection pad through the opening portion of the mask.

8. A method of manufacturing a semiconductor device, according to claim 4, wherein the step of forming the bump electrode includes,
arranging the semiconductor wafer to direct the connection pad downward,
arranging ball case in which a large number of conductive balls are housed, under the semiconductor wafer, and
making the conductive ball to adhere onto an adhesive material provided on the connection pad by flying the conductive ball toward the semiconductor wafer side while vibrating the ball case up and down.

9. A method of manufacturing a semiconductor device, according to claim 4, wherein the step of forming the insulating dam layer is the step of,
forming a resist on the semiconductor wafer, and forming the opening portion in the resist by a photolithography.

10. A method of manufacturing a semiconductor device, according to claim 4, after the step of forming the bump electrode, further comprising the step of:
obtaining individual semiconductor devices each formed of a semiconductor chip by cutting the semiconductor wafer, in a state that the insulating dam layer is removed or still left.
